(19) United States
(12) Patent Application Publication
(10) Pub. No.: US 2017/0012155 A1
(43) Pub. Date: Jan. 12, 2017

(54) SYSTEM AND METHOD FOR MANIPULATING SOLAR ENERGY

(71) Applicant: ARIZONA BOARD OF REGENTS ON BEHALF OF ARIZONA STATE UNIVERSITY, Scottsdale, AZ (US)

(72) Inventors: Zachary C. Holman, Phoenix, AZ (US); Roger Angel, Tucsoon, AZ (US); Brian Wheelwright, Tucson, AZ (US)

(21) Appl. No.: 15/116,442

(22) PCT Filed: Feb. 3, 2015
(86) PCT No.: PCT/US2015/014259

§ 371 Date: Aug. 3, 2016

Related U.S. Application Data
(60) Provisional application No. 61/935,233, filed on Feb. 3, 2014.

(51) Int. Cl. H01L 31/056; H01L 31/054; H02S 40/44; H01L 31/048

(52) U.S. Cl. CPC H01L 31/056; H01L 31/048; H01L 31/0547; H02S 40/44

(57) ABSTRACT

An apparatus for generating electricity from solar radiation having a solar spectrum is provided. The apparatus includes a photovoltaic mirror comprising a plurality of photovoltaic cells, the photovoltaic mirror configured to separate the solar spectrum, absorb a first portion of the solar spectrum, and concentrate a second portion of the solar spectrum at a focus. The apparatus also includes an energy collector spaced from the photo-voltaic mirror and positioned at the focus, the energy collector configured for capturing the second portion of the solar spectrum.

### CROSS-REFERENCE To RELATED APPLICATIONS

This application is based on, claims the benefit of, and incorporates herein by reference U. S. Provisional Application No. 61/935,233 filed on Feb. 3, 2014.

### STATEMENT REGARDING FEDERALLY SPONSORED RESEARCH

This invention was made with government support under DE-AR0000474 awarded by U. S. Department of Energy. The government has certain rights in the invention.

### BACKGROUND

The present disclosure relates generally to systems and methods for renewable energy and, in particular, to systems and methods for generating energy from solar radiation.

Geographical regions with high insolation in the United States, such as the Arizona area, generally may average up to 6.0 kWh/m² per day for the direct sunlight accessible to trough tracking systems, and up to 8.0 kWh/m² per day for direct and diffuse solar component accessible via photovoltaic (PV) modules, affording a significant source of energy.

The current state of the art in solar thermal energy generation typically involves concentrating power plant systems that employ mirrors or lenses to focus large areas of sunlight onto a small area. Electrical power is then produced when the concentrated light is converted to heat, which may drive an engine or turbine connected to an electrical power generator. Some systems are fitted with parabolic trough mirrors, consisting of curved glass and chemically-deposited silver films on the rear surfaces of the troughs. For example, the projected output from the Solana concentrating solar plant located outside the Phoenix, Arizona area is around 944 GWh per year. With total reflector areas up to several square kilometers, trough reflectors in the Arizona area are usually oriented about an N-S axis and designed to keep direct sunlight focused on a receiver tube at the parabola focus using active sunlight tracking, and may achieve up to 94% reflectivity. Solana averages up to 1.18 kWh/m² per day, which corresponds to a conversion efficiency of 19.6% of the direct sunlight or 14.7% relative to the total solar resource. The plant is able to store heat sufficient for 6 hours of overnight generation at 280 MW, namely, 0.76 kWh/m² per day, and thus must generate at least 0.41 kWh/m² per day by direct conversion of heat. The energy flow path for an illustrative parabolic trough concentrating solar power plant, using the Advanced Research Projects Agency- Energy (ARPA-E) prescribed 10-hour storage split and loss figures prescribed in the Full-Spectrum Optimized Conversion and Utilization of Sunlight (FOCUS) Funding Opportunity Announcement, is shown in FIG. 1A. With a total sunlight-to-electricity conversion efficiency of 13.1% in this example, the concentrating solar power (CSP) plant is relatively inefficient, but has the benefit of being wavelength indiscriminate and producing a considerable fraction of dispatchable power, which is valued at a premium of 1.5× by ARPA-E.

By contrast, state-of-the-art photovoltaic energy generation implemented in large scale installations commonly includes, among others, monocrystalline silicon photovoltaic panels, described by a spectral band gap, which can directly convert up to 21.5% of the total solar resource into electricity. Photovoltaic modules often consist of a sheet of glass on the side facing the sun, which allows light to pass while protecting the semiconductor wafers from the elements. In large scale applications, photovoltaic modules are mounted on single-axis trackers, similar to the trough mirrors. For coverage of an area similar to the Solana power plant, namely 2.2 km², photovoltaic panels on single-axis trackers would generate 1.72 kWh/m² per day, or a 46% gain in total energy output over Solana, but would have no overnight generation component. FIG. 1B shows the breakdown of photovoltaic power by input from the direct and diffuse components, as well as spectral band. The diffuse input is 25% of the total, and half of the output energy comes from the near infra-red (NIR) band, with wavelengths between 700 nanometers and 1000 nanometers, though this band makes up only 29% of the total input. Additionally, only a small region in the infra-red (IR) band, with wavelengths greater than 1000 nanometers, is above the band gap, and hence the overall IR efficiency of 9%. Moreover, further losses up to 4% are due to inverter losses in the direct to alternating current conversion.

Comparing photovoltaic and thermal generation in broad terms, a trough concentrator solar power plant has the advantage of having dispatchable, nighttime output, making use of the full solar spectrum, but operates at a low overall efficiency, in part because of diffuse component losses. On the other hand, photovoltaic modules make use of the diffuse component, and are very efficient up to the mid-range of the solar spectrum, but less so in the rest of the spectrum.

In addition, some solar collector systems have attempted to concurrently generate electricity while transferring residual heat to an engine. In such systems, sunlight is typically concentrated onto a topping device, such as a photovoltaic cell, which is backed by a thermal exchanger intended to provide heat removal for use in a heat engine. However, such designs have strong limitations due to competing efficiency requirements for each energy generating element. Specifically, the efficiency of the photovoltaic cell decreases with temperature, while that of the heat engine increases. Moreover, using concentrated sunlight at a photovoltaic topping device poses additional problems in that fabrication of photovoltaic cells that can successfully operate at a few hundred degrees Celsius may be challenging and more costly.

Therefore, given the above, there is a need for improved systems and methods to efficiently convert solar radiation to other forms of energy, including electrical, thermal, and chemical energy.

### SUMMARY

The present disclosure overcomes the aforementioned drawbacks by providing an apparatus for energy generation by way of utilizing the different parts of the solar spectrum in an efficient manner. In one embodiment, the apparatus provided directs appropriate portions of the solar spectrum to the different energy conversion elements, which may be physically separable, the elements configured for efficient energy conversion using those portions. For example, the near NIR spectrum, including its diffuse component, may be converted to electricity using silicon-based photovoltaic cells, while the remaining direct sunlight may be reflected to a heat engine to generate heat for storage and dispatchable thermal energy conversion, another higher- or lower-band gap photovoltaic cell, or a combination thereof. In this manner, the photovoltaic elements may operate at ambient temperatures, which increases efficiency and reduces unwanted heat-related losses, while a heat engine can operate over a wide range of temperatures, increasing its effectiveness.

In accordance with one embodiment, the present disclosure provides an apparatus for converting energy from solar radiation having a solar spectrum. The apparatus includes a photovoltaic mirror having a plurality of photovoltaic cells. The photovoltaic mirror is configured to separate the solar spectrum, absorb a first portion of the solar spectrum, and concentrate a second portion of the solar spectrum at a focus. The apparatus further includes an energy collector spaced from the photovoltaic mirror and positioned at the focus. The energy collector is configured for capturing the second portion of the solar spectrum.

In one aspect, the photovoltaic mirror includes at least one filter for diverting the second portion of the solar spectrum to the focus. In another aspect, the at least one filter comprises an optical coating structured to reflect a range of wavelengths of the solar radiation. In yet another aspect, the at least one filter comprises at least a first layer and a second layer, the first layer having a refractive index different from the second layer. In a still another aspect, the wavelengths are shorter than 700 nanometers. In a further aspect, the wavelengths are larger than 1000 nanometers.

In one aspect, the plurality of photovoltaic cells has a band gap, and the range of wavelengths is a sub-band gap range. In another aspect, the plurality of photovoltaic cells generates electricity from a range of absorbed wavelengths representative of a super-band gap range. In yet another aspect, the filter includes an optical coating on at least one of the plurality of photovoltaic cells. Each optical coating is structured to reflect a range of wavelengths. In still another aspect, the filter includes at least a first layer and a second layer. The first layer has a refractive index different from the second layer. In a further aspect, the wavelengths are shorter than 700 nanometers.

In one aspect, the plurality of photovoltaic cells has a band gap, and the range of wavelengths is a sub-band gap range. In another aspect, the plurality of photovoltaic cells generates electricity from a range of absorbed wavelengths representative of a super-band gap range. In yet another aspect, the photovoltaic mirror comprises at least one of a transparent parabolic trough, a dish, and a heliostat. In still another aspect, the transparent parabolic trough comprises glass. In a further aspect, the photovoltaic cells are affixed to a support.

In one aspect, the photovoltaic cells face the sun and are attached to a non-sunward side of the photovoltaic mirror. In another aspect, the photovoltaic cells cover 10% to 100% of a surface of a support. In yet another aspect, the photovoltaic cells are affixed to a support via an encapsulation or lamination process. In still another aspect, the photovoltaic cells comprise at least one of crystalline silicon, cadmium telluride, and copper indium gallium selenide. In a further aspect, the photovoltaic cells comprise monocrystalline silicon.

In one aspect, the photovoltaic cells comprise polycrystalline silicon. In another aspect, the photovoltaic cells are sufficiently flexible so as to conform to a curvature of a support. In yet another aspect, at least some of the plurality of photovoltaic cells includes a rear reflector. In still another aspect, the rear reflecting coating comprises a metal layer. In a further aspect, the photovoltaic cells are substantially planar.

In one aspect, the photovoltaic cells comprise amorphous silicon/crystalline silicon heterojunction photovoltaic cells. In another aspect, the energy collector comprises a heat engine. In yet another aspect, the energy collector comprises a chemical reaction vessel. In still another aspect, the energy collector comprises at least one of a second plurality of photovoltaic cells. In a further aspect, the second plurality of photovoltaic cells is positioned at the focus for capturing at least some of the second portion of the solar spectrum.

In one aspect, solar radiation absorbed in the photovoltaic cells generates electricity, and solar radiation not absorbed in the photovoltaic cells is reflected and focused on the energy collector. In another aspect, the support comprises an optical coating structured to reflect a range of wavelengths. In a further aspect, the photovoltaic mirror is segmented.

The foregoing and other advantages of the disclosure will appear from the following description.

### BRIEF DESCRIPTION OF THE DRAWINGS

FIG. 1A is a schematic illustration representing thermal energy generation by way of a parabolic trough.

FIG. 1B is a schematic illustration representing photovoltaic energy generation by way of a photovoltaic module.

FIG. 2A is a schematic of an example apparatus, for use in accordance with the present disclosure.

FIG. 2B is a schematic of another example apparatus, for use in accordance with the present disclosure.

FIG. 3 is a graphical illustration representing the spectral reflectance as a function of wavelength for an embodiment of a silicon-based photovoltaic cell with a dichroic layer according to the present disclosure.

FIG. 4A is a graphical illustration of calculated exergy efficiency (solid lines) as a function of wavelength for embodiments of an apparatus using a realistic efficiency of 70% of the Shockley-Queisser (S-Q) limit and a heat engine operating at two-thirds of the Carnot limit, with temperatures between 200° C. and 700° C. The solid line curve indicated by “a” represents calculated exergy efficiency for a cell band gap of 2.5 eV and the solid line curve indicated by “b” represents calculated exergy efficiency for a cell band gap of 1.7 eV. Solid line curves intermediate a and b correspond to cell band gaps intermediate 1.7 eV and 2.5 eV. The dotted line curve indicated by “c” represents the individual exergy contribution from the photovoltaic cells located on the support for 70% of the S-Q limit. Dashed lines represent the energy contribution from the energy collector. The dashed line curve indicated by “d” represents a heat engine operating at two-thirds of the Carnot limit at a temperature of 200° C., and the dashed line curve indicated by “e” represents a heat engine operating at two-thirds of the Carnot limit at a temperature of 700° C.

FIG. 4B is a graphical illustration of an example of exergy efficiency curves computed for four different long-pass filters having cutoff wavelengths of 500 nm (triangles), 600 nm (diamonds), 700 nm (squares), and 800 nm (circles), respectively, for efficiencies of 70% of the S-Q limit, and a heat engine operating at two-thirds of the Carnot limit. The data point indicated by “f” represents 82% heat exergy for a long-pass filter cutoff wavelength of 800 nm, while the data point indicated by “g” represents 52% heat exergy for a long-pass filter cutoff wavelength of 500 nm.

FIG. 5 is a graphical illustration of the breakdown of spectral power conversion as a function of wavelength for a silicon solar cell operating at the Shockley- Queisser limit.

FIG. 6 is schematic illustrating a cross-sectional view of an example apparatus design for use in accordance with the present disclosure.

FIG. 7 is a schematic illustrating a cross-sectional view of another example apparatus design for use in accordance with the present disclosure.

FIG. 8 is a graphical illustration representing a simulation of optical performance as a function of wavelength for a 48-layer TiO₂/SiO₂ stack for use in accordance with the present disclosure.

FIG. 9A is a schematic illustrating an example structure of a silicon heterojunction photovoltaic cell for use in accordance with the present disclosure,

FIG. 9B is a graphical illustration representing spectral performance (i.e., external quantum efficiency and [1-reflectance]) as a function of wavelength for the silicon heterojunction photovoltaic cell of FIG. 9A. Region I: Front surface reflection (1.4 mA/cm²=3.0%); Region II: Escape reflection (1.3 mA/cm²=2.8%); Region III: Blue parasitic absorption (1.5 mA/cm²=3.2%); Region IV: IR parasitic absorption (2.4 mA/cm²=5.3%); Region V: Aperture area J_{SC} (36.7 mA/cm²=79.8%); Grid shadowing (2.8 mA/cm²=6.1%).

FIGS. 10A-10C are schematics illustrating example apparatus designs for use in accordance with the present disclosure. FIG. 10A shows the path of direct light on a segmented photovoltaic mirror with relatively few segments. FIG. 10B shows the path of diffuse light on the photovoltaic mirror of FIG. 10A. FIG. 10C shows the path of direct light on a segmented photovoltaic mirror with a greater number of segments as compared with the photovoltaic mirror of FIG. 10A.

FIGS. 11A and 11B are schematic illustrating example system designs combining multiple example apparatuses for use in accordance with the present disclosure. FIG. 11A shows an example of how the photovoltaic mirror of FIG. 10A may be arranged to cover a larger field or area. FIG. 11B shows an example of how the photovoltaic mirror of FIG. 10C may be arranged to cover a larger field or area.

FIG. 12 is a schematic illustration representing energy generation by way of a parabolic photovoltaic mirror.

FIG. 13A is a schematic illustration of a first embodiment of a photovoltaic mirror having a flat high band gap cell and specular reflector.

FIG. 13B is a schematic illustration of a second embodiment of a photovoltaic mirror having a textured high band gap cell and an optical filter.

FIG. 13C is a schematic illustration of a third embodiment of a photovoltaic mirror having a low band gap cell and an optical filter.

FIG. 14 is a schematic illustration of a segmented photovoltaic mirror having flat photovoltaic segments arranged into a curvature to concentrate light on the receiver.

FIG. 15A is a plot of calculated external quantum efficiency as a function of wavelength for hypothetical CdMgTe and silicon heterojunction (SHJ) photovoltaic cells.

FIG. 15B is a plot of spectral efficiency as a function of wavelength for both CdMgTe and SHJ photovoltaic cells.

FIG. 16 is a plot of optical coating reflectance and transmittance, photovoltaic cell spectral efficiency, and CSP system efficiency without storage losses as a function of wavelength.

FIG. 17 is a plot of system efficiency without thermal storage for a photovoltaic mirror (PVMirror)/CSP hybrid system. Contours represent the hybrid system efficiency, with line contours indicative of the PVMirror/CSP power-output split in percentage of photovoltaic. Dashed lines represent cut-off wavelengths of 1000 nm, 1100 nm, and 1200 nm respectively.

FIG. 18 is a plot of system efficiency with thermal storage for a PVMirror/CSP hybrid system. Contours represent the hybrid system efficiency, with the line contours representative of PVMirror/CSP power-output split in percentage of photovoltaic. The cut-off wavelength is fixed at 1100 nm.

### DETAILED DESCRIPTION

The present disclosure describes an approach to converting solar radiation into other forms of energy that includes features and functionalities intended for maximizing use of different portions of the solar spectrum, thus increasing the efficiency of solar energy usage. In one embodiment, the present disclosure provides an apparatus designed to separate the spectrum of incident solar radiation, absorb a first portion of the spectrum using a number of photovoltaic cells arranged about a support, and direct, a second, concentrated portion of the spectrum to an energy collector located generally about a focus of the directed second portion of the spectrum. As will become apparent, the apparatus of the present disclosure may be used in combination with any systems and infrastructure necessary for operation of the apparatus, and could be included or replicated in assemblies or structures designed for achieving a desired energy output or providing a specific area coverage.

In one aspect of the present disclosure, the apparatus is configured for separating the solar spectrum into different portions for use by elements suited for efficient energy capture and conversion of those portions of the spectrum, as will be described. Specifically, the apparatus may include any elements, or components, configured with capabilities intended for spectral separation. Such capabilities may be provided by way of features or structures comprising layers, films, coatings, or materials capable of performing spectral separation, filtering, or reflection. For example, optical filters included may comprise long-pass filters, with cutoff wavelengths. In one embodiment, the cutoff wavelength may be less than about 700 nm. In another embodiment, the cutoff wavelength may be a different value. Further, the features or structures may provide one or more surfaces that are textured, porous, polished smooth, or a combination thereof. In one aspect, the features or structure may be arranged as a singular layer, stacked, or the like. In another aspect, the features or structure may be manufactured using known technologies. Further, the features of structures may have properties designed to facilitate selecting or filtering light of any desired range of wavelengths, or energies. Such filtering capabilities may be incorporated within either of the support or photovoltaic cell designs. However, in some envisioned designs, it may be useful to provide a combination of spectrally dependent elements or components configured for both supports and photovoltaic cells.

In another aspect of the present disclosure, an apparatus may be configured to absorb a first portion of the solar spectrum by way of a number of photovoltaic cells arranged about a support. Photovoltaic cells absorb photons with specific energies in relation to a semiconductor band gap, creating electron-hole pairs, or excitons, and separating the created charge carriers for use in generating electricity. Example photovoltaic cells include silicon-based cells, (e.g., silicon homojunctions, amorphous silicon/crystalline silicon heterojunctions), thin-film cells, (e.g., CdTe, CIGS, ZnSe, CdS, a-Si:H), III-V cells (e.g., GaAs, InP, AlGaAs), and multi-junction cells. In general, photovoltaic cells may be described by band gaps in a range between 0.5 eV and 2.5 eV, although other values may be possible. In some embodiments, photovoltaic cells may be configured to convert photons from the solar spectrum with energies above the band gap. In one example, the photovoltaic cells absorb those photons as described herein. The portion of the solar spectrum not absorbed by the photovoltaic cells may be in a sub-band gap energy range, and could be directed and concentrated at an energy collector. In some embodiments of a photovoltaic mirror, the directing may be achieved by reflection. For example, the reflecting element may be a metallic layer. In yet other embodiments, an energy collector may be placed at the focus, which may be a point, a line, a plane, or another focus arrangement.

In one aspect, photovoltaic cells may inherently facilitate a splitting of the solar spectrum by preferentially absorbing a first portion of the solar spectrum that includes photons with energies for use in generating electricity using the photovoltaic cells. The portion of the solar spectrum that is absorbed may depend on the band gap of the photovoltaic cells. In embodiments in which the natural above-band gap absorption of the photovoltaic material provides the spectrum splitting, the direction of sub-band gap photons towards a focus may be performed by a reflecting element disposed at the rear of the photovoltaic cell. In another aspect, photovoltaic cells may also be configured to facilitate a spectral separation, or filtering, by way of elements or components, configured therein. Specifically, the photovoltaic cells may include optical layers, films, coatings, materials, or combinations thereof designed for transmitting, filtering, reflecting or redirecting any portion of the spectrum. For example, the photovoltaic cells may include transparent, dichroic, metallic, insulating, polymeric, semi-conducting, or filtering layers, or the like.

In some configurations, it may be useful to control portions of the solar spectrum from reaching active regions of the photovoltaic cells, since photons with energies in those portions could result in heat generation in the photovoltaic cells, which may decrease the efficiency of the photovoltaic cell. More generally, some wavelengths that would naturally be absorbed in the photovoltaic cells may be better utilized by an energy collector placed at the focus of the photovoltaic mirror. Therefore, some designs may include optical layers, films, coatings or materials, configured for reflecting and redirecting light in a range of wavelengths. In one example, a design may employ long-pass filters with cutoff wavelengths less than about 700 nanometers, although other values are possible. In this manner, select wavelengths may be allowed to traverse into the active regions of the photovoltaic cells, thus retaining operating temperatures of the photovoltaic cells in a range that facilitates enhanced efficiency. Furthermore, other configurations may include features or elements, which may be spectrally selective, and designed to recover a portion of the solar spectrum not absorbed by the photovoltaic cells, such as light in a sub-band gap energy range. Another example may include a free-standing film composed of polymer layers that act as an optical filter. The film may be placed in front of the photovoltaic cells (e.g., during attachment of the cells to a glass support) or placed in front of the support. In one aspect, the film may be composed of polymer layers with varying refractive indices, including birefringent polymer layers. The layers may have refractive indices and thicknesses such that the film behaves as a long-pass filter, a short-pass filter, or a band-pass filter. One example of a suitable long-pass filter includes the 3MTM Visible Mirror Film.

Generally, it may be useful to provide photovoltaic cells that are free from parasitic absorption in order to increase the energy conversion efficiency of the photovoltaic cell. In one aspect, parasitic absorption may occur due to, for example, band gap or free-carrier absorption in regions of the photovoltaic cell besides the intended absorbing region. However, an apparatus according to the present disclosure may be configured to circumvent parasitic absorption in order to utilize all portions of the solar spectrum. In one embodiment, an optical filter may be used to reflect wavelengths for which a photovoltaic cell has appreciable parasitic absorption, directing these wavelengths to the energy collector at the focus of the photovoltaic mirror.

In embodiments employing an optical filter besides the natural absorptive filtering of the photovoltaic cell itself, it may be useful for the optical filter to exhibit unity reflectance at wavelengths for which reflection is designated, and unity transmittance at wavelengths for which transmission is designated. However, an apparatus according to the present disclosure may tolerate less than ideal optical filters. In one aspect, non-unity reflectance at wavelengths for which reflection is designated may result in energy conversion in the photovoltaic cells if, for example, the transmitted light is absorbed in the photovoltaic cells. In another aspect, non-unity transmittance at wavelengths for which transmission is designated may result in energy conversion in the collector at the focus of the photovoltaic mirror if, for example, the reflected light is absorbed in that collector. Therefore, the apparatus is amenable even when using simple, inexpensive, optical filters.

The photovoltaic cells of the present disclosure may be designed in various shape and sizes, and may be assembled in various geometrical arrangements or modules on one or more supports (e.g., structures, substrates, optics, or the like) to provide a photovoltaic mirror. The photovoltaic cells may further be planar, near planar, textured, rigid, flexible, or fashioned to conform to any shape, such as the general shape of the support. In one aspect, the photovoltaic cell may provide coverage of up to 100% of the surface of the support. In another aspect, the photovoltaic cell may provide coverage of at least about 10% of the support. In yet another aspect, the photovoltaic cell may provide coverage of at least about 50% of the support. In some embodiments, the photovoltaic cells may be elements separate from, movably coupled to, or otherwise attached to the support. In other embodiments, the photovoltaic cells may be affixed to the support via an encapsulation, a lamination or other fabrication process, as in the case of silicon photovoltaic cells. In yet other embodiments, the photovoltaic cells may be incorporated within or deposited, fabricated, or grown directly on the support to form a continuous coating or layered structure, as in the case of thin-film photovoltaic cells.

In another aspect, an embodiment of an apparatus may include a support that provides a foundation for, or incorporates the photovoltaic cells. Further, the support may concentrate a separated, second portion of the solar spectrum, including light not absorbed by the photovoltaic cells, such as light in a sub-band gap range. However, it will be appreciated that the support or elements fixed thereupon (e.g., photovoltaic cells, optical filters, or the like) may concentrate the separated, second portion of the solar spectrum. The support may include any number of features, or elements for achieving a particular functionality, such as light transmission, spectral filtering, spectrally selective reflection, and the like. In one aspect, the functionality may be achieved by way of layers, films, coatings, structures, another like feature, or a combination thereof. For example, the photovoltaic mirror or the support, in particular, may include transparent, dichroic, metallic, or like filtering layers. Additionally (or alternatively), the support may be designed and operated in cooperation with any supplementary systems or structures configured for use with the apparatus. In particular, the support may include any additional components intended to provide protection, rigidity, or capabilities for maintaining or modifying desired orientations with respect to any direction of incident solar radiation.

In one aspect, a photovoltaic mirror may reflect light via a spectrum-splitting optical filter or via a reflective backing of the photovoltaic cell (i.e., a surface of the photovoltaic cell opposing a front surface upon which an incoming source of light is initially incident). To concentrate a second portion of solar radiation not absorbed by the photovoltaic cells, the shape of the support may be designed to have or include elements or surfaces that are generally oriented to facilitate directing the reflected light toward a common location, or focus. For example, the support shape may be a trough, parabola, dish, or a more complex shape that may include curved or planar segments. Generally, the photovoltaic cells or spectrum-splitting optical filter may conform to the shape of the support, either affixed to or integrated within the support. The different segments, sections, modules, planar or curved portions of the support, or photovoltaic cells thereabout, may be configured to have reflecting elements oriented generally toward the focus, in dependence of the incident and reflected radiation directions. It will be appreciated that embodiments of a photovoltaic mirror having a conformal optical filter, the photovoltaic cells disposed behind the optical filter may be arranged in a non-conformal manner. In some designs of the present disclosure, the curvature, geometry and surface area of the support, or photovoltaic cells thereabout, may be designed to achieve a desired efficiency in directing non-absorbed sunlight at the focus, or in accordance with a particular level of concentration, described by a concentration factor. For example, concentration factors may have values in a range between 1× and 45,000×, although other values are possible.

In some embodiments, a support may be any suitable material such as glass, metal, plastic, the like, and combinations thereof. Further, photovoltaic cells, optical filters, or other components of a photovoltaic mirror may be placed on either the front (sunward) or back of the support. For example, the photovoltaic cells and any optical filters may be affixed to the front of a curved or segmented aluminum support. Alternatively (or in addition), the photovoltaic cells and any optical filters may be affixed the back of a curved or segmented glass support. In yet other embodiments, the photovoltaic cells may be affixed to the back of a curved or segmented glass support, while any optical filters may be affixed to the front of the support. Other combinations and arrangements may also fall within the scope of the present disclosure.

In another aspect, a photovoltaic mirror may be mounted on a tracking device designed to track the position of the sun in the sky. This may be a tracker of any design, such as a tracker with a North-South axis designed to track the sun in one direction, a two-axis tracker that always points directly at the sun, or a two-axis tracker used as a heliostat. The photovoltaic mirror may be mounted upon the tracker using any suitable method.

Photovoltaic mirrors according to the present disclosure may be provided across a broad range of size-scales. For example, a photovoltaic mirror may have a surface area of between about 1 mm² and about 1 km². In one embodiment, multiple photovoltaic mirrors with sizes of about 1 mm² to about 1 cm² may be arranged to cover a larger area. In another embodiment, trough-shaped or dish-shaped photovoltaic mirrors with concentrating photovoltaic (CPV) cells at their foci may be packaged between a transparent front sheet and a protective rear sheet to form a module. Such a module may be mounted on a single sun tracker. Photovoltaic mirrors with sizes of about 100 cm² to about 1 km² may each be placed on sun trackers, which may be arranged to act individually or collectively to produce energy. For example, planar photovoltaic mirrors with sizes of about 1 m² may be mounted on two-axis sun trackers as heliostats, their collective reflected light converging on a focus where a thermal receiver or other energy collector may be located. In yet another embodiment, parabolic trough photovoltaic mirrors with sizes of about 100 m² may be arranged in series on a single-axis sun tracker with, for example, a thermal receiver tube or photovoltaic cells at their collective line focus. Such large photovoltaic mirrors may be segmented as, for example, is common for concentrated solar power trough mirrors.

In yet another aspect, the apparatus or photovoltaic mirror may include an energy collector for receiving a second portion of the solar spectrum not absorbed by the photovoltaic cells. The energy collector may be generally located about the focus of the photovoltaic mirror, in spaced relation to the support and photovoltaic cells, and configured for receiving concentrated light from the photovoltaic mirror. In addition, the energy collector may include elements and capabilities designed for making use of the portion of the solar spectrum not absorbed by the photovoltaic cells, employing systems and infrastructure appropriate for extracting, storing, or converting energy received by the energy collector.

In some embodiments, the energy collector may include a thermal absorber. In one aspect, the energy collector may serve as a hot source for a heat engine configured for generating electricity using thermal energy. For example, the energy collector may be a black tube, pipe, or vessel containing a thermally absorbing medium or fluid (e.g., synthetic oil). The energy collector may be controlled and operated in accordance with a specific application or temperature requirement. In other designs, the energy collector may include any number of photovoltaic cells designed to efficiently operate using the concentrated portion of the solar spectrum directed by the photovoltaic mirror. Such photovoltaic cells may be configured with a band gap or band gaps that may be different from that of photovoltaic cells located about the support. In yet other designs, the energy collector may include any number of chemical reaction vessels or containers. Such configurations may utilize concentrated light from the photovoltaic mirror to control any segment or activity in relation to one or more chemical reactions present in at least one chemical reaction vessel or container.

Features and advantages of the present disclosure will become apparent in the following description. The specific examples offered are for illustrative purposes only, and are not intended to limit the scope of the present disclosure in any way. Indeed, various modifications of the disclosure in addition to those shown and described herein will become apparent to those skilled in the art from the aforementioned description and fall within the scope of the appended claims. For example, certain arrangements and configurations are presented, although it may be understood that other configurations may be possible, and still considered to be well within the scope of the present disclosure. Likewise, specific process parameters, materials and methods are recited that may be altered or varied based on a number of variables.

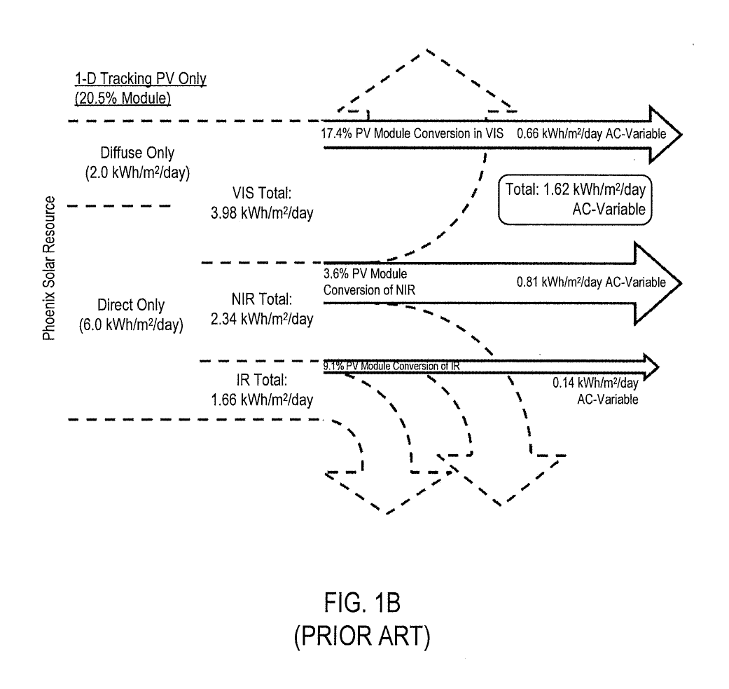

A non-limiting example of a first apparatus 200 and a second apparatus 200′ in accordance with the present disclosure are illustrated in FIGS. 2A and 2B, respectively. Each of the apparatus 200 and apparatus 200′ includes a photovoltaic mirror 202 or photovoltaic mirror 202′ and an energy collector 204. The photovoltaic mirror 202 includes a plurality of photovoltaic cells 206 arranged on a support 208. As illustrated, the photovoltaic mirror 202 is configured to direct a portion 210 of the solar spectrum 212 to the energy collector 204, which is concentrated by way of the configuration of the photovoltaic mirror 202. The support 208 may be any transparent or semi-transparent material. For example, the support 208 may be glass. The photovoltaic cells 206 may be affixed by any means to the back or distal side 208a of the support 208 with respect to a direction of incident solar radiation. In other configurations (not shown), the photovoltaic cells 206 may be additionally or alternatively affixed on the frontal or proximal side 208b of the support 208. The support 208 may also be fitted with or connected to a secondary support or other like structures (not shown) to facilitate operation of the apparatus 200 or apparatus 200′.

The support 208 or photovoltaic cells 206 may include any number of optical layers, films or coatings, with properties designed to facilitate redirecting of a portion of the solar spectrum. In certain configurations, short-pass, long-pass or band- pass optical filters may be useful to provide additional flexibility in comparison to other approaches. For example, by changing a cutoff of a long-pass filter, certain operational parameters of the apparatus 200 or apparatus 200′ may be tuned to accommodate requirements of a specific application, such as a ratio of heat to electricity exergy.

As shown in FIG. 2A and 2B, the apparatus 200 or apparatus 200′ may perform spectral filtering, selective spectral reflection, or another like function, such as concentrating a non-absorbed portion of the solar spectrum 212, in dependence of the arrangement and optical properties of optical layers, films or coatings configured therein. With reference to FIG. 2A, the photovoltaic mirror 202 may include wide-band gap photovoltaic cells 206 and no optical coating so that sub-band gap near-infrared and infrared light may be reflected. By comparison, FIG. 2B shows the photovoltaic mirror 202′ with silicon photovoltaic cells 206 and an optical coating (not shown) that reflects wavelengths shorter than 700 nm, resulting in visible and infrared (from the back of the photovoltaic cell) light being reflected while near-infrared light is absorbed. In other embodiments, optical coatings may be applied to an apparatus to reflect to a focus solar light defined by wavelengths shorter than about 700 nanometers, whereas other optical coatings may be capable of reflecting to a focus solar light defined by wavelengths longer than about 1000 nm. In yet other embodiments, an apparatus may be configured to reflect to a focus solar light defined by additional or alternative ranges of wavelengths.

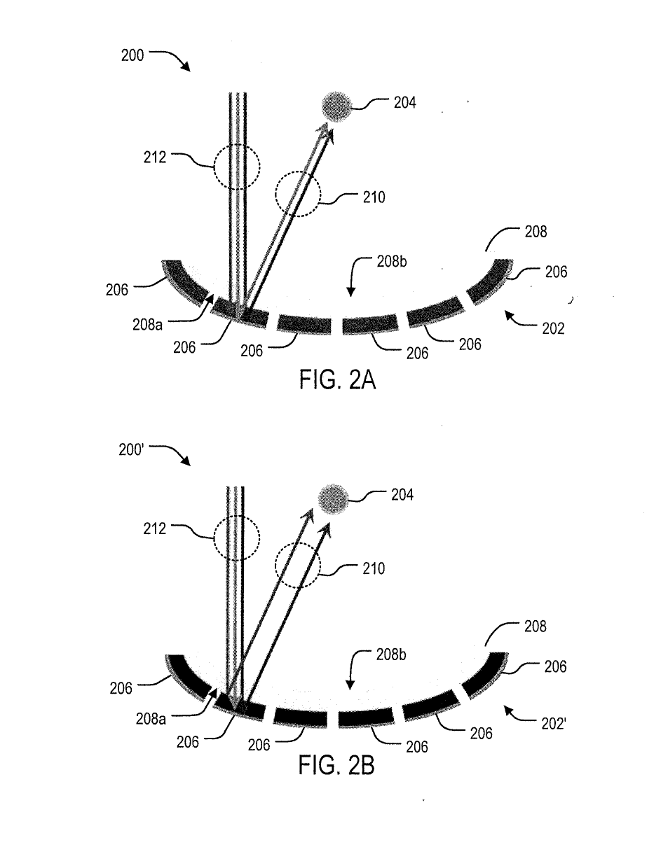

Referring to FIG. 3, it will be appreciated that reflectance may vary as a function of wavelength as in the case of a silicon-based photovoltaic cell with a long- pass optical filter. For example, in region I of FIG. 3, a front surface of an apparatus may be highly reflective for wavelengths of less than about 600 nm. In region II of FIG. 3, light is generally absorbed by the apparatus in the range of about 600 nm to about 1000 nm. By comparison, for wavelengths of greater than about 1000 nm, an apparatus may be configured for nearly 100% escape reflectance as see for region III of FIG. 3. Alternatively, reflectance for wavelengths of greater than about 1000 nm may be achieved by a band-pass, rather than long-pass, optical filter at the front surface. In some aspects, metallic coatings, such as silver films, may be positioned at the back of a photovoltaic cell to recover and redirect non-absorbed light by specular reflection.

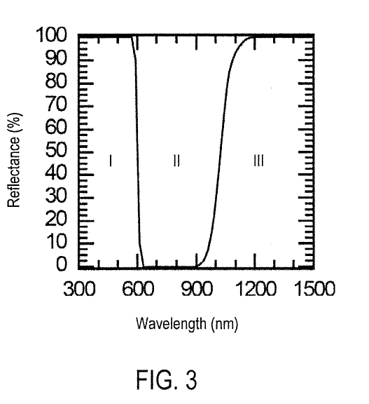

In some embodiments, the energy collector 204 may be a thermal absorber. Turning to FIGS. 4A and 4B, it may be seen that an apparatus according to the present disclosure may meet requirements by certain applications to have 50% to 90% of the delivered exergy be heat. Calculated exergy efficiency varies depending at least in part on cell band gap. Using photovoltaic cells with band gaps in a range between 2.0 and 2.5 eV, the exergy efficiency of an apparatus in accordance with the present disclosure may be between about 35% and about 45% (FIG. 4A). FIG. 4B illustrates the exergy efficiencies that are possible for long-pass filters of varying cutoff wavelength.

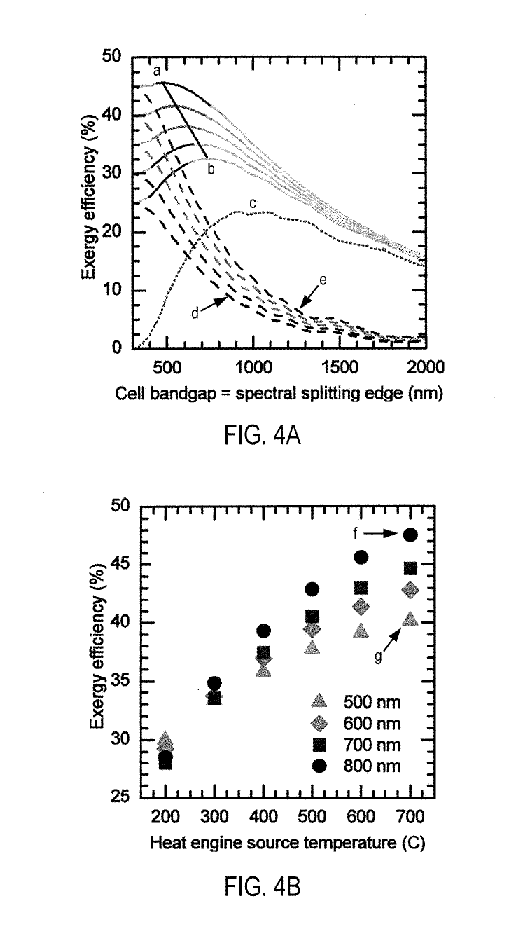

FIG. 5 shows an example of spectral intensity versus wavelength for solar irradiation and the maximum utilization of this irradiation by a silicon solar cell. In this example, wavelengths above about 1100 nm are not absorbed (region a), while wavelengths below about 1100 nm are distributed between thermalization (region b), extraction losses (region c) and available power (region d). Due to silicon's small band gap (compared to a band gap of about 2.0 eV to about 2.5 eV for achieving exergy efficiency of about 35% to about 45% as in FIG. 4A), the majority of the power at wavelengths below approximately 600 nm is lost as heat (region b). Accordingly, it may be useful to provide an apparatus including an energy collector for utilizing at least a portion of the power lost as heat.

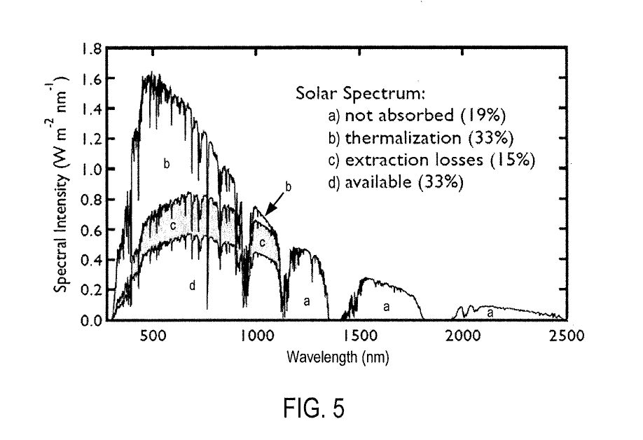

Turning to FIG. 6, another non-limiting example of an apparatus 220 for use in accordance with the present disclosure may include a photovoltaic cell 222 having a back reflector 224 and a glass support 226. The example depicts how separation of the solar spectrum is achieved. As shown, a majority of the solar spectrum with energies above a band gap (super-band gap light 228) may be absorbed by the photovoltaic cell 222 while a majority of the non-absorbed sub-band gap light 230 may be redirected to an energy collector (not shown) via the back reflector 224. A first portion 232 of the sub-band gap light 230 may be reflected off the front surface 226a of the glass support 226 towards the energy collector (not shown) in the direction indicated by the arrows “A”. A second portion 234 of the sub-band gap light 230 may be reflected off the back reflector 224 towards the energy collector. In one example, the first portion 232 may be about 4% of the sub-band gap light 230 and the second portion 234 may be about 96% of the sub-band gap light 230. In another aspect, a first portion 236 of the super-band gap light 228 may be reflected off the front surface 226a of the glass support 226 towards the energy collector. A second portion 238 of the super-band gap light 228 may be collected from the apparatus 220 as direct current (DC) electrical energy. In one example, the first portion 236 may be about 4% of the super-band gap light 238.

In designing the photovoltaic cell 222 for use in an apparatus 220, it may be useful to consider that the size of the band gap may be related to the amount of light reflected for subsequent use by the energy collector. In one aspect, an apparatus having a narrow band gap may inefficiently convert photons with energies much larger than the band gap. In another aspect, a photovoltaic cell having a wide band gap may efficiently convert the absorbed photons, with a small proportion of photons absorbed by the photovoltaic cell. Accordingly, it may be useful to select an intermediate band gap that balances conversion and reflection.

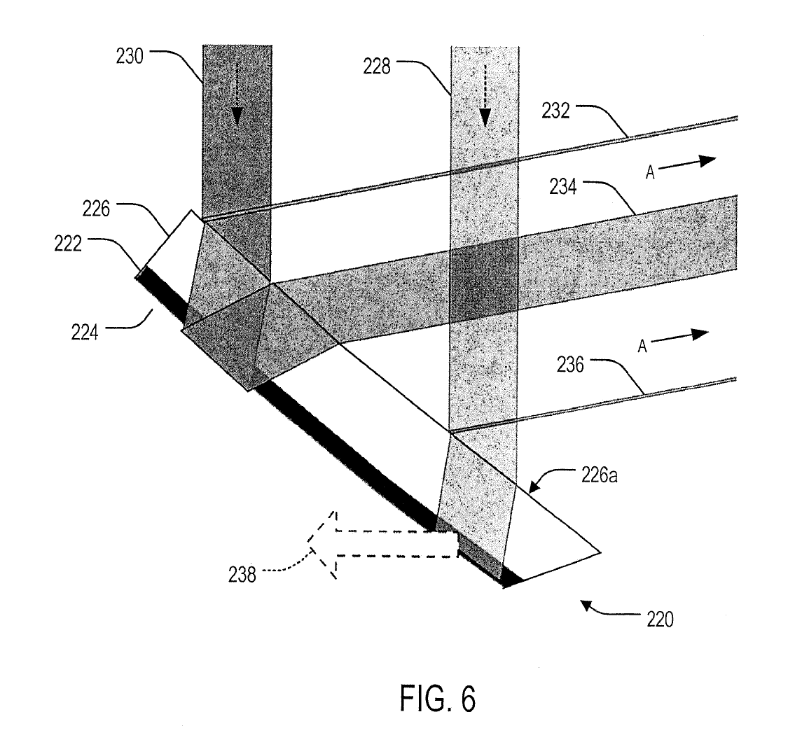

With reference to FIG. 7, an apparatus 240 for use in accordance with the present disclosure may include a photovoltaic cell 242, a back reflector 244 and a glass support 246. In one aspect, the photovoltaic cell 242 may be an SHJ cell. As shown, separation of the solar spectrum may be achieved by way of configurations intended for reflecting nearly all the visible light 248 (i.e., wavelengths less than 700 nanometers) and most the of the IR light 250 (i.e., wavelengths greater than 1000 nm), while transmitting near-infrared NIR light 252 (i.e., wavelengths between 700 nm and 1000 nm) for high-efficiency conversion by the photovoltaic cell 242. As shown, at least one optical filter 254 may be applied to a front surface 246a or a rear surface 246b of the glass support 246 covering the photovoltaic cell 242, or included as a free-standing film between the glass support 246 and the photovoltaic cell 242. In one aspect, the optical filter 254 may be configured to prevent visible light 248, as well as some IR light 250 from entering the photovoltaic cell 242. Any IR light 250 transmitted by the optical filter 254 may be reflected at the back of the photovoltaic cell 242 via the back reflector 244. Thus, the NIR light 252 may be absorbed in the photovoltaic cell 242 and converted to DC electrical energy 256 with a projected efficiency of up to 60%, while other wavelengths are reflected.

In one aspect, a first portion 258 of the IR light 250 may be reflected off the front surface 246b of the glass support 246 towards the energy collector (not shown) in the direction indicated by the arrows “A”. A second portion 260 of the IR light 250 may be reflected off the optical filter 254 towards the energy collector. A third portion 262 of the IR light 250 may be reflected off the back reflector 244 towards the energy collector. In one example, the first portion 258 may be about 4% of the IR light 250, and the combination of the second portion 260 and the third portion 262 may be about 96% of the IR light 250. In another aspect, a first portion 266 of the visible light 248 may be reflected off the front surface 246b of the glass support 246 towards the energy collector. A second portion 268 of the visible light 248 may be reflected off the optical filter 254 towards the energy collector. In one example, the first portion 266 may be about 4% of the visible light 248, and the second portion 268 may be about 96% of the visible light 248. In yet another aspect, a first portion 270 of the NIR light 252 may be reflected off the front surface 246b of the glass support 246 towards the energy collector. As described above, another portion of the NIR light 252 may be collected as electrical energy 256. In one example, the first portion 270 may be about 4% of the NIR light 252.

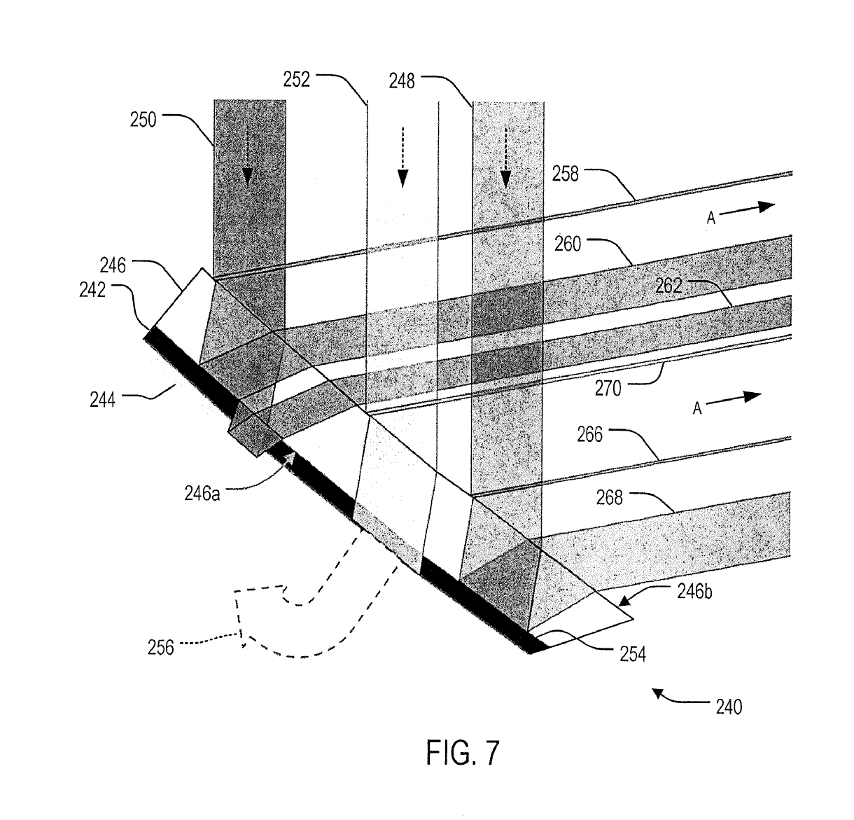

In some embodiments, optical filters may be constructed from a stack of high- and low-refractive-index dielectric or polymer layers. FIG. 8 illustrates an example of simulated performance of a multi-layer titanium dioxide/silicon dioxide (TiO₂/SiO₂) stack, illustrating reflectance and transmittance properties as a function of wavelength. In one example, the stack may act as a band-pass filter that blue-shifts with off-axis illumination. In one aspect, the blue-shift may change the photovoltaic/energy collector split diurnally and annually but not dramatically alter the system efficiency. As seen in FIG. 8, the wavelength-dependent properties of the optical filter may facilitate transmittance of NIR light while reflecting shorter and longer wavelengths. In some designs, non-unity reflectance below about 700 nm may be acceptable since those transmitted photons are well above the band gap of silicon and may drive an SHJ or other photovoltaic cell. In some embodiments, since the photovoltaic cells themselves may reflect sub-band gap photons, the dichroic filter need not be specifically designed to also reflect these long wavelengths unless specular reflection from the photovoltaic cells is incomplete.

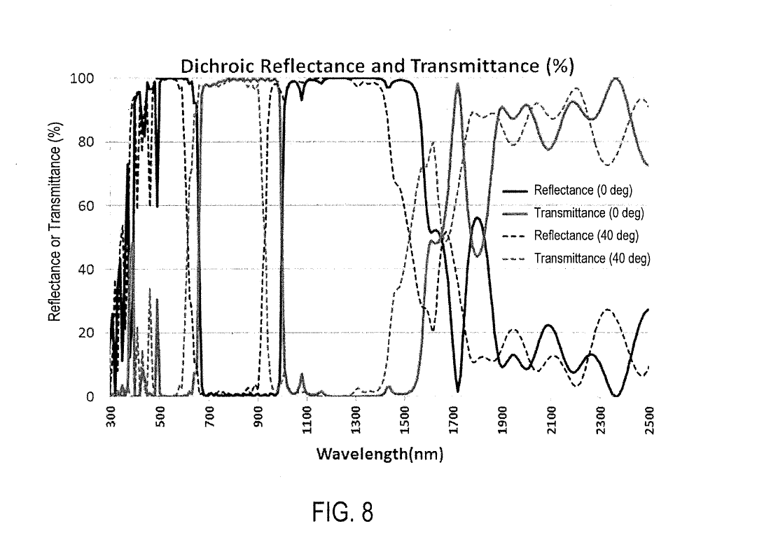

In some embodiments, an apparatus may include a multitude of amorphous silicon/crystalline silicon SHJ photovoltaic cells 280 as shown in FIG. 9A. Each photovoltaic cell 280 may include a base layer 282, intermediate layers 284, 286, 288, 290, 292, and 294, and a surface layer 296. The photovoltaic cell 280 may further include one or more contacts 298. In one example, the base layer 282 and the contacts 298 may be silver, while the intermediate layer 284 and the surface layer 296 may be transparent conductive oxides (TCO). Further, the intermediate layer 286 may be (n⁺) hydrogenated amorphous silicon (a-Si:H), the intermediate layer 288 may be a-Si:H(i), the intermediate layer 290 may be (n) crystalline silicon (c-Si), the intermediate layer 292 may be a-Si:H(i), and the intermediate layer 294 may be a-Si:H(p⁺). With reference to FIG. 9B, an accounting of optical losses of the photovoltaic cell 280 under AM1.5G illumination illustrates that near-perfect conversion of non-reflected may be achieved, where AM1.5 refers to the air mass coefficient for 1.5 atmosphere thickness, which corresponds to a solar zenith angle of 48.2°, and G refers to the global (direct plus diffuse) spectrum.

In one aspect, SHJ cells may have a surface passivation layer that is semiconducting rather than insulating, thereby allowing the metal contacts 298 to be displaced from the wafer surface layer 296 without inhibiting charge collection. This may result in open-circuit voltages that are higher than in silicon diffused-junction solar cells. In large part because of their high open-circuit voltage, such SHJ cells have high conversion efficiencies under full-spectrum one-sun illumination. Although such cells may possess a weaker blue response due to parasitic absorption in the front amorphous silicon layers, such a feature may be less important in the context of the present disclosure given that these wavelengths may be reflected from the front surface. Consequently, SHJ cells may have higher conversion efficiency (greater than 40%) for the NIR spectrum compared to other silicon-based photovoltaic cells. In addition, SHJ cells may be fabricated on thin wafers, which may allow conformality to a curved glass support as the cells are flexible and the maximum temperature during fabrication (e.g., about 200° C.) may prevent bowing. With respect to planarization and optical filter deposition, SHJ cells may be adapted to be specular and highly reflective at IR wavelengths.

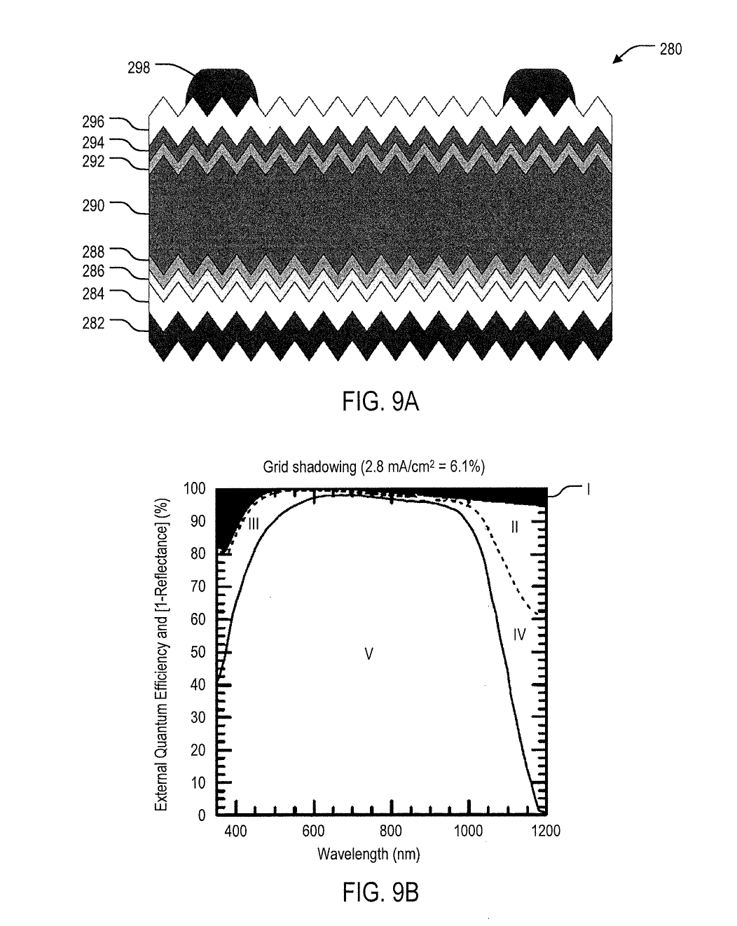

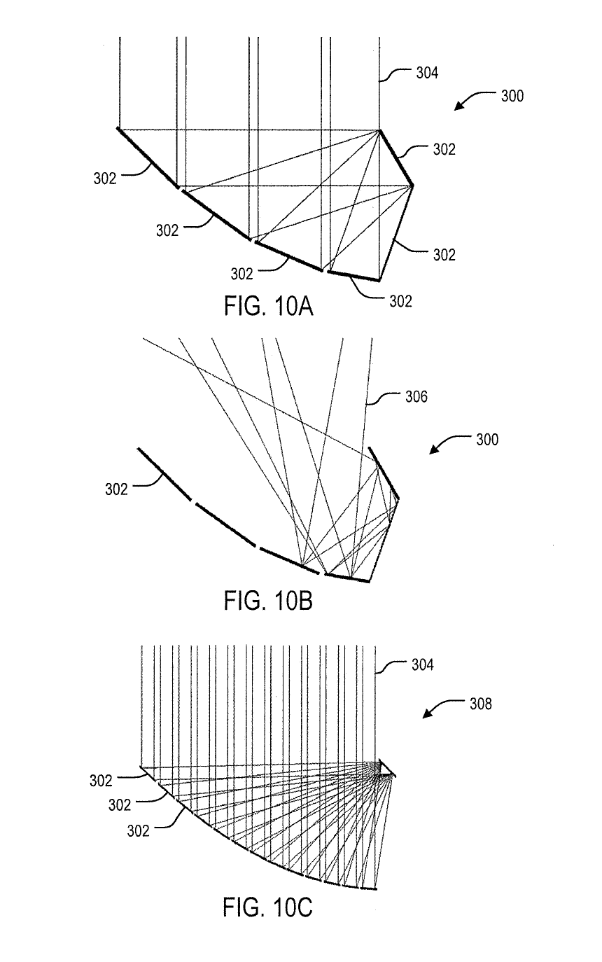

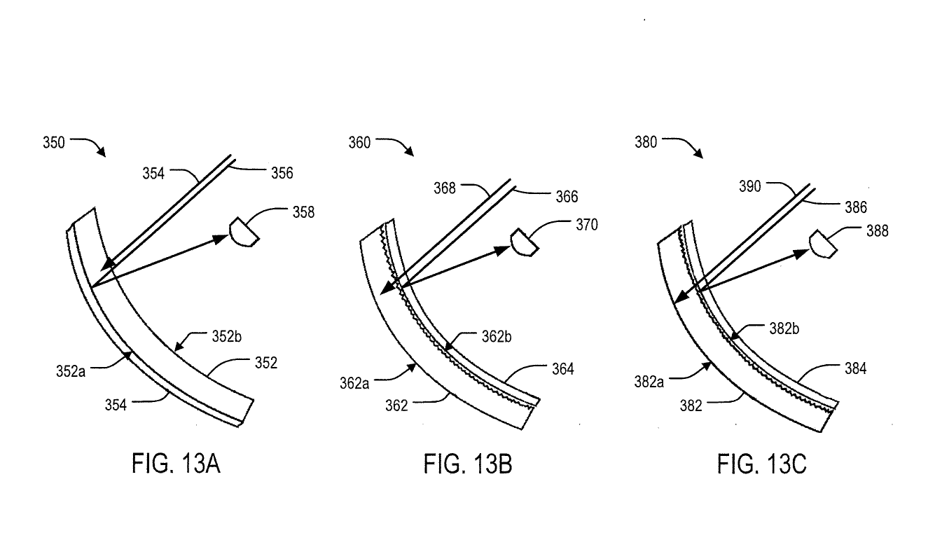

FIGS. 10A-10C illustrate that embodiments of segmented photovoltaic mirrors may be used under both direct and diffuse illumination conditions. In a first example, a photovoltaic mirror 300 may include a plurality of segments 302. Each segment 302 may include a photovoltaic cells disposed on a planar supports such as a glass strips. In one example, each segment 302 may mounted to a steel frame on a tracker, with the segments 302 arranged to approximate a focusing optic (see also FIG. 14). The photovoltaic mirror 300 may be configured for use with a direct light 304 (FIG. 10A), a diffuse light 306 (FIG. 10B), or a combination thereof. Embodiments of a photovoltaic mirror may further include any number of segments 302. For example, the photovoltaic mirror 300 includes 6 segments (FIGS. 10A and 10B), whereas an embodiment of a photovoltaic mirror 208 shown in FIG. 10C includes 14 segments. FIGS. 11A and 11B illustrate how the photovoltaic mirror 300 and photovoltaic mirror 308, respectively, may be serially combined in any dimensions in accordance with desired area coverage or performance.

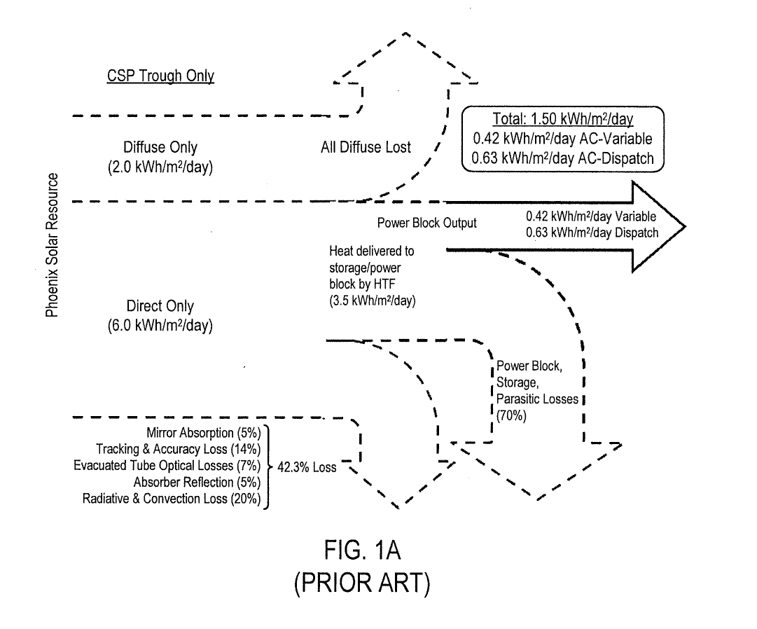

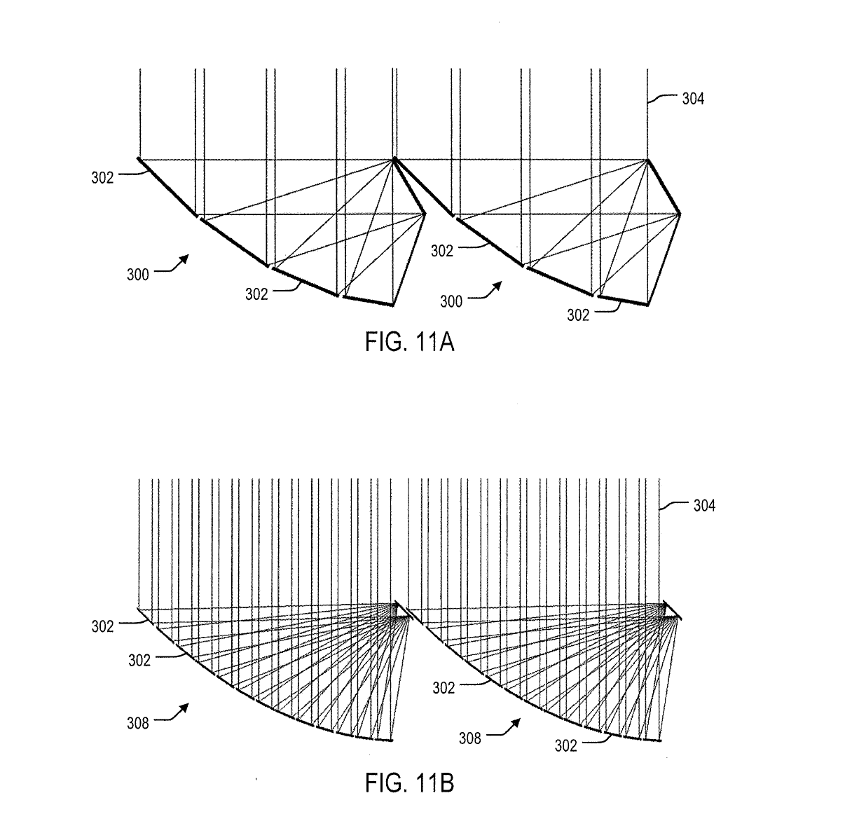

FIG. 12 shows a schematic depicting performance over the full solar spectrum for an example photovoltaic mirror power plant employing the approach of the present disclosure. In one aspect, the NIR band may directed to a multitude of SHJ or other like photovoltaic cells, for highest conversion, while the remaining direct light may be directed to a thermal engine. Compared to previous technologies shown in FIGS. 1A and 1B, two possible outputs are shown in FIG. 12. In one aspect, the Total A is representative of power generated using the storage specified by ARPA-E, and the Total B is representative of power generated using a higher storage ratio. Therefore, with the ARPA-E specified storage of 10 hours, embodiments of a photovoltaic mirror power plant may produce about 70% of the dispatchable electricity of a CSP plant, while increasing the variable output nearly three-fold, for a total power conversion efficiency just shy of a traditional photovoltaic power plant. As shown, Total B has a storage ratio such that the dispatchable energy matches that of the CSP power plant example of FIG. 1A.

Embodiments of an apparatus may be provided for use in power plant systems, with potential for rapid commercialization facilitated by compatibility with present technologies. For example, a trough power plant with a given total power output, when equipped or modified in accordance with the present disclosure, may preserve substantially all of the dispatchable capability while more than doubling the variable output. Specifically, the anticipated cost increase for modifications or upgrades in accordance with the present disclosure may only be about 29% of the cost of the parabolic mirror field while the overall solar-to-electrical power conversion efficiency is increased from about 13.1% to about 19.5%, a relative gain of about 49%.

In summary, traditional photovoltaic systems may be inefficient in large part because certain portions of the solar spectrum are not absorbed, and the excess energy is lost as heat. In addition, CSP systems are inefficient because, though they make use the full solar spectrum, there are many steps in the energy conversion process, each of which causes an appreciable (wavelength-independent) efficiency loss. Previous attempts to harness both technologies have resulted in hybrid photovoltaic and concentrating solar systems, whereby hot photovoltaic cells under concentration are coupled with a thermal cycle. In these systems, the photovoltaic cells double both as electricity generators and a heat source. One drawback of such a setup is that the maximum theoretical efficiency of a photovoltaic cell decreases rapidly with increasing temperature.

By contrast, embodiments of the present disclosure may overcome the limitations by capitalizing on the high conversion efficiency of photovoltaic cells over a narrow wavelength range, and the moderate conversion efficiency of CSP systems at all wavelengths. In one aspect, the present disclosure may provide an apparatus that separates the solar spectrum, transmitting selected wavelengths to photovoltaic cells for efficient electricity generation, while diverting and concentrating the remaining portion of the spectrum at a focus for subsequent use. The present disclosure includes an approach that increases the efficiencies of energy conversion elements included in the apparatus. For example, photovoltaic cells located on a support may absorb near-band gap wavelengths of the solar spectrum, while reflecting other wavelengths to an energy collector via the photovoltaic mirror configuration. In so doing, the present disclosure may convert sunlight more efficiently into electricity, as compared to either stand-alone photovoltaic or concentrating solar power systems.

In another aspect, the present disclosure may provide an apparatus that facilitates a thermal decoupling between photovoltaic cells located about the support, and the energy collector. Thus, the photovoltaic cells may receive one-sun illumination (i.e., unconcentrated sunlight that naturally illuminates the surface of the earth) and be able to operate at advantageous temperatures, say below 100° C., without need for additional cooling systems, thereby reducing dark current and increasing efficiency. In this manner, the energy collector may operate over a wider range of temperatures, which may be beneficial for systems that are efficient at higher temperatures, such as thermal engines.

### EXAMPLES

### Example 1

The heliostat field of a tower CSP plant has both the largest cost of any individual sub-system and the largest potential for cost reduction. One route to cost reduction is to modify the heliostats to increase the efficiency with which sunlight is converted into electricity, thereby generating more power with nominally the same heliostat field. In one aspect, it may be possible to boost the power output of a tower CSP plant by about 50%.

In one aspect, losses associated with the heliostat field may occur when diffuse light is not focused on the tower and instead is lost. Further losses may arise due to heliostat inefficiency. For example, a portion of the heliostats may not be pointed at the tower to smooth out power generation. In one embodiment, a spectrum-splitting heliostat with integrated power generation may be provided to overcome at least a portion of these losses.

In one example heliostat field, silvered glass or aluminum mirrors may be replaced with photovoltaic mirrors comprised of photovoltaic cells or modules and an optical filter. In one example, the photovoltaic mirrors may be comprised of thin-film photovoltaic modules with wavelength-selective polymer mirrors adhered to their front surfaces. The polymer mirror may reflect light with wavelengths greater than about 700 nm to the tower (e.g., for heat generation) while transmitting shorter wavelengths to the photovoltaic module. In one aspect, the photovoltaic module may convert the shorter-wavelength light to electricity. The absorber in the photovoltaic modules may have a band gap that is matched to the 700 nm transmitting-to-reflecting transition. Photovoltaic modules including a-Si:H meet this criterion. In one aspect, a-Si:H is relatively efficient for wavelengths above its band gap, where the average conversion efficiency of an a-Si:H photovoltaic cell may be about 24% for wavelengths of 400-700 nm. In some embodiments, additional or alternative photovoltaic technologies may be used.

For embodiments of a heliostat having a perfect wavelength-selective mirror, about 50% of the incident direct solar power (wavelengths greater than about 700 nm) may be delivered to the tower for conversion to electricity with an assumed photon-to-electricity conversion efficiency of about 20%. The other half of the direct light, plus 70% of the diffuse light (which is itself 20% to 45% of the total insolation, depending on location) may be transmitted to the photovoltaic module and converted to AC electricity with an efficiency of about 23%. The net result is about a 28% increase in the total power output of the CSP plant compared to the similar plant using silvered mirrors. However, this may be an underestimate of the gain because the 20% standby mirrors that generate no power in a tower CSP plant under normal operating conditions may instead be pointed at the sun, generating electricity from their photovoltaic modules. In one aspect, this may boost the power output by about an additional 19%, for a total gain of about 47%.

In one aspect, for oblique incidence, a mirror may lose its spectrum-splitting behavior and reflect all wavelengths, particularly for s-polarized light. This may not be a loss, but rather it alters the ratio of light coupled to the photovoltaic module and the tower, which may be advantageous. Secondary advantages may include that all light less than about 700 nm may be absorbed in the photovoltaic module rather than reflected. Accordingly, the heliostats may have no visible glare. Further, standby heliostats may not only generate power when in standby, but may also be nearly as effective as silvered mirrors in the morning and evening when they are reflecting to the tower. This may be possible if the heliostats far out in the field between the sun and tower assume this role, because the angle of incidence on these heliostats may be grazing, for which some polymer mirrors become a nearly wavelength-agnostic reflector. In yet another aspect, the photovoltaic modules may begin producing electricity as soon as the sun rises, whereas the turbine requires that the tower first heat up. Integration of photovoltaics into the heliostats may thus help smooth out power generation. For example, smoother power generation may be achieved if a plant is not equipped with all-night storage. Finally, with the tower receiving only infrared wavelengths, it may be possible to design an improved selective absorber since it is generally easier to design for optical performance over a narrower wavelength range. This may, for example, enable absorbers that can withstand higher temperatures, further increasing the efficiency of the thermal cycle.

### Example 2

In another example, the present disclosure provides a tandem solar collector system or photovoltaic mirror. In one embodiment, the photovoltaic mirror is a photovoltaic device that may act as a concentrating mirror, spectrum splitting medium and high efficiency light-to-electricity converter. The photovoltaic mirror may convert at least a portion of the diffuse spectrum in addition to the direct beam. Further, the photovoltaic mirror may be used to couple two photovoltaic cells of different technologies or even one photovoltaic cell with a non-photovoltaic energy collector. The photovoltaic mirror may free up the choice of top and bottom photovoltaic cells without any lattice-matching or current-matching restrictions. For a hypothetical high-band gap photovoltaic mirror, a photovoltaic mirror paired with a lower-band gap photovoltaic cell to form a tandem photovoltaic collector may outperform monolithic tandem photovoltaic cells under the same illumination. Moreover, by using SHJ cells in photovoltaic mirrors paired with a CSP system, a hybrid system having efficiency as high as a pure photovoltaic system may be achieved. The system may further have thermal storage capability.

A photovoltaic mirror may employ a one-sun photovoltaic cell as a spectrum splitter. One embodiment may be realized with a high-band gap cell with a specular rear reflector by using the band gap as a spectrum-splitting edge. In one aspect, the photovoltaic mirror may reflect non-absorbed light rather than transmitting it. Further, by arranging the photovoltaic cells on a support so that specularly reflected light from many individual cells arrives at a common focus (e.g., as with a trough, dish or linear Fresnel optic), the concentrated light may be used to illuminate another concentrated photovoltaic cell, power a thermal cycle, or power another system. Another example of a photovoltaic mirror includes an optical filter on top of a photovoltaic cell. The filter may be of any type, band gap, or surface morphology to split the incoming light spectrum.

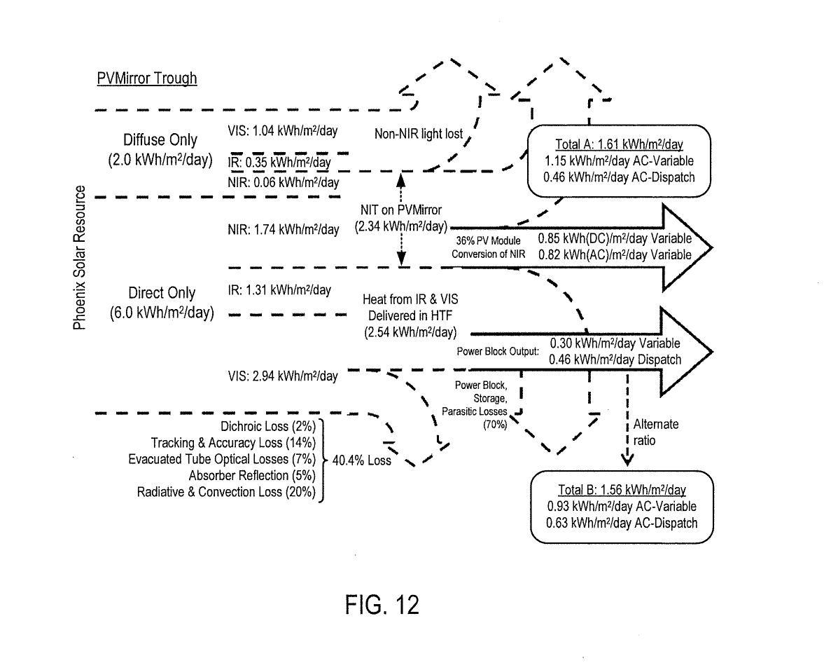

With reference to FIG. 13A, an embodiment of a photovoltaic mirror 350 in a trough geometry may use a planar high-band gap photovoltaic cell 352 and a specular rear reflecting mirror 354 on the back surface 352a of the photovoltaic cell 352. The photovoltaic mirror 350 may absorb substantially all of the super-band gap wavelengths 354 while specularly reflecting all or a portion of the sub-band gap light 356 to a low band gap photovoltaic cell or other energy collector 358 positioned at a common focus. The collector 358 may use (e.g., absorb or transform) the concentrated light.

Another embodiment of a photovoltaic mirror 360 in FIG. 13B may have a high-band gap photovoltaic cell 362 having a back surface 362a and a front surface 362b. The front surface 362b may be textured as compared with the flat front surface 352b as in FIG. 13A. In this case, sub-band gap light 366 reflected at or near the back surface 362a of the photovoltaic cell 362 may be scattered by the texture. Accordingly, it may be useful to provide a spectrally selective optical filter 364 disposed at or on the front surface 362b of photovoltaic cell 362 that only allows super-band gap light 368 to be transmitted while specularly reflecting all sub-band gap light 366 to an energy collector 370 positioned at the focus. The optical filter 364 may be a band-pass filter that may be tuned to transmit only light to the high band gap photovoltaic cell 362 that the cell may effectively convert to electrical energy. The textured front surface 362b may allow better light trapping of the light transmitted through the coating 364.

Turning to FIG. 13C, a third embodiment of a photovoltaic mirror 380 may include a low-band gap photovoltaic cell 382 (e.g., a silicon cell) having a back surface 382a and a front surface 382b. In one aspect, tuning an optical filter 384 positioned on the front surface 382b may enable substantially all short-wavelength photons 386 to be reflected to an energy collector 388 at the focus while long-wavelength photons 390 may be utilized by the photovoltaic cell 382.

In some embodiments a photovoltaic mirror may include photovoltaic cells disposed on curved glass. However, as shown in FIG. 14, an embodiment of a photovoltaic mirror 400 may include photovoltaic cells 402 disposed on flat glass segments 404. The photovoltaic cells 402 may be arranged into a particular curvature to absorb a first portion of light 406, and reflect a second portion of light 408 toward an energy collector 410 positioned at the focus. Accordingly, the photovoltaic mirror 400 may include a back reflector 412 applied to one or more of the photovoltaic cells 402. Additionally (or alternatively), photovoltaic cells may be disposed on a flexible metal sheet, a layer of plastic, or a metal foil. The metal or plastic may be bent into a particular shape, or laminated. For wafer-type cells, lamination to curved glass or flat glass sections may be useful.

In one aspect, a photovoltaic mirror may be curved or segmented with an optical filter or specular back reflector. For cells having an optical filter, photovoltaic cells with any existing textures may be used, while for cells having a back reflector, an optically flat or specular surface may be used. The flat surface may be provided by conformal layers (thin films) or planar wafers. In the case of silicon photovoltaic cells, an HF/HNO₃ acid-based chemical polishing process or a mechanical polishing process may be used to achieve an optically flat surface. The optical filter may be sputtered onto the inner side of an encapsulating cover material (e.g., glass, plastic, or the like), though other embodiments are also possible.

### Example 2A

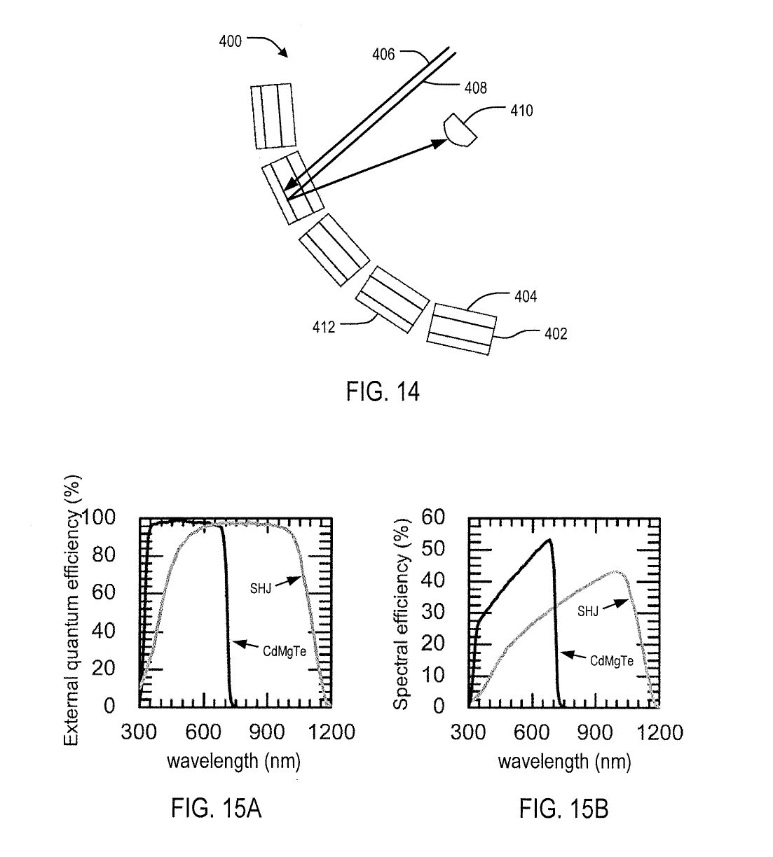

Silicon tandem photovoltaic cells may include silicon paired with one or more additional materials, such as GaInP, GaAsP, halide perovskites, or CdTe-based materials. Example CdTe-based materials include ternary alloy semiconductors of CdTe with Zn, Mn, and Mg. In the present example, a hypothetical tandem photovoltaic cell includes a CdMgTe photovoltaic cell having a 1.8 eV band gap and an efficiency of 21.7% under one-sun AM1.5G illumination paired with a 22%-efficient SHJ cell. The hypothetical external quantum efficiency (EQE) curve and other key one-sun parameters of each cell used in this example are shown in FIG. 15 and Table 1. The short-circuit current density (J_{SC}) values were calculated from EQE curves, and the hypothetical EQE curve of a 1.8 eV CdMgTe cell was obtained by shifting the EQE curve of a record CdTe cell (Green et al., Prog Photovoltaics, 2013, 21, 827-837). The J_{SC} value was calculated to be 20.37 mA/cm². The open-circuit voltage (V_{OC}) was hypothesized to be 1.31 V for the CdMgTe cell. The spectral efficiency shown in FIG. 15B was calculated by the following equations:

$$Efficiency ( λ ) = {J}_{SC} ( λ ) \cdot {V}_{OC} \cdot FF$$

$${J}_{SC} ( λ ) = q \frac{λ}{hc} EQE ( λ ) F ( λ )$$

where F (λ) is the spectral irradiance of AM1.5G spectrum and λ is the wavelength in nm. This spectral efficiency plot was used to predict tandem device performance.

TABLE 1

| Cell | η (%) | E_{g} (eV) | V_{OC} (V) | J_{SC} (mA-cm⁻²) | FF (%) |
|---|---|---|---|---|---|
| CdMgTe | 21.7 | 1.8 | 1.31 | 20.37 | 79.0 |
| SHJ | 22.4 | 1.1 | 0.73 | 22.38 | 79.0 |

In one embodiment of the present disclosure, the CdMgTe top cell is arranged into a segmented parabolic shape as a photovoltaic mirror as in FIG. 14 with the SHJ cell as the bottom cell located at the focus. The performance of this photovoltaic mirror tandem system was simulated assuming 20× concentration at the focus, and the result was compared with that of a monolithic tandem (employing the same sub-cells) both under one-sun illumination and 20× concentration. All three configurations were on a North-South-axis tracking system. The efficiencies were calculated under AM1.5G illumination for all three cases. However, direct light and diffuse light were treated separately for the photovoltaic mirror tandem, as only the CdMgTe photovoltaic cell receives diffuse light in the present photovoltaic mirror tandem approach. No efficiency loss in any of the cells was assumed during tandem formation (i.e., no optical losses for the photovoltaic mirror, or current-matching, or lattice-matching losses in the monolithic tandems). The efficiencies reflected the maximum attainable efficiencies given the sub-cells and the chosen tandem configurations. Table 2 shows the resulting tandem efficiencies and outdoor performance for both Phoenix, Arizona and Miami, Fla., which have diffuse light fractions of about 25% and about 44%, respectively.

TABLE 2

| | 20X | One-Sun | 20X |
|---|---|---|---|
| | Photovoltaic | Monolithic | Monolithic |
| | Mirror Tandem | Tandem | Tandem |
| Current Matching | Not required | Required | Required |
| Lattice Matching | Not required | Required | Required |
| Diffuse Light | 300-700 | 300-1200 | None |
| Collection (nm) | | | |
| Material | Full area | Full area | 1/20 area |
| Consumption | CdMgTe, | CdMgTe | CdMgTe |
| | 1/20 area Si | and Si | and Si |
| In-Lab Efficiency | 34.30 | 33.13 | 35.56 |
| (%, One-Sun | | | |
| AM1.5 G) | | | |
| Solar Resource | Direct light: 6 kwh/m²/day; Diffuse light: | | |
| (Phoenix) | 2 kwh/m²/day | | |
| Energy Output | 2.74 | 2.65 | 2.13 |
| (kwh/m²/day) | | | |
| Solar Resource | Direct light: 3.6 kwh/m²/day; Diffuse light: | | |
| (Miami) | 2.8 kwh/m²/day | | |
| Energy Output | 2.20 | 2.12 | 1.28 |
| (kwh/m²/day) | | | |

The 20× monolithic tandem had the highest in-lab efficiency, but also had the lowest outdoor energy output as it loses all diffuse light energy. This discrepancy became larger when the system was operating at locations with higher diffuse light fraction (e.g., Miami). For example, with an energy output of 1.28 kwh/m²/day, the out-door annual solar efficiency was only 20%, which was significantly lower than the 35.51% in-lab efficiency. The 20× photovoltaic mirror tandem had the highest energy output of the three cases in Table 2. Further, the 20× photovoltaic mirror tandem had slightly higher efficiency than the one-sun monolithic tandem in current-matched conditions as the bottom silicon cell is under concentrations that improve efficiency. As the diffuse spectrum is blue-shifted compared to the direct spectrum, even though the bottom cell does not receive any of the diffuse light, the top cell may effectively capture most of the diffuse light. The one-sun monolithic tandem output was close to the photovoltaic mirror tandem, but the levelized cost of electricity (LCOE) would be higher considering it consumes 20× more silicon cells than a photovoltaic mirror system given the same balance-of-system cost.

In some applications, the photovoltaic mirror tandem system may have better performance than the other two tandem approaches. In one aspect, the coupled photovoltaic cells may be manufactured separately, which allows for freedom of process optimization for each individual cell. Further, there may be few or no process compatibility issues in fabricating the devices. In another aspect, monolithic tandems may experience optical losses between photovoltaic cells, electrical losses from recombination junctions, or the like. In a further aspect, as current mismatch frequently occurs in real meteorological conditions, monolithic tandems may have higher losses even when fabricated with an optimized current-matched design, whereas photovoltaic mirrors may not be adversely affected by real meteorological conditions.

### Example 2B

Embodiments of a photovoltaic mirror may be used in other reflection-based concentrating solar applications. For example, a photovoltaic mirror may be included as a component of a trough reflector, heliostat, parabolic dish, or Fresnel reflector CSP systems. Generally, all three photovoltaic mirror configurations as shown in FIGS. 13A-13C may be used for each of the aforementioned types of CSP systems. In one aspect, incorporating photovoltaic mirrors into a CSP may provide a more efficient hybrid system.

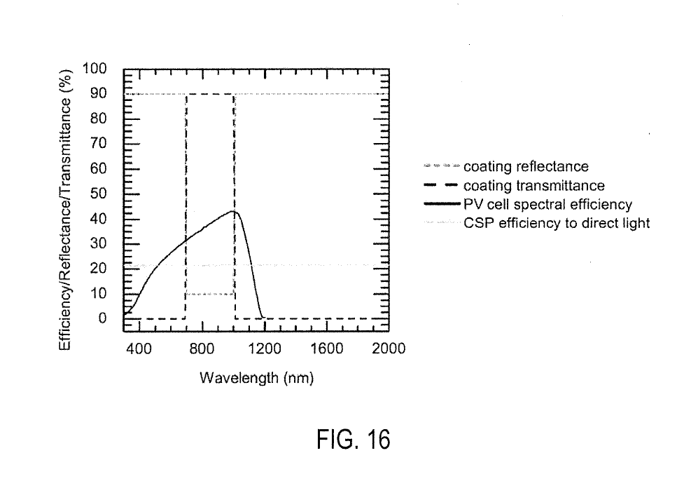

A hybrid system was modeled using the methodology as in Example 2A, but with an optical filter on top of SHJ photovoltaic cells affixed to a parabolic trough support to form a photovoltaic mirror. The SHJ cell parameters used in this example were also the same as in Example 2A. FIG. 16 shows the optical filter (“coating”) performance, SHJ (“PV cell”) spectral efficiency and CSP efficiency, which was independent of wavelength. For a 22%-efficient SHJ cell, the spectral conversion efficiency at a wavelength of 1000 nm may be as high as 40%, and even 48%. The CSP system had an assumed electrical energy conversion efficiency of 21.4% for direct light, with loss mechanisms that account for this efficiency listed in Table 3, where the CSP efficiency was the system efficiency for incoming direct light without thermal loss in storage.

TABLE 3

| | | Receiver | Receiver | | Thermal |
|---|---|---|---|---|---|
| CSP | Rankine | Optical | Thermal | Parasitic | Loss in |
| Efficiency | Efficiency | Loss | Loss | Loss | Storage |
| 21.4% | 35% | 12% | 20% | 10% | 9% |

From the spectral efficiency plot shown in FIG. 16, it may be useful to provide a band of light to the SHJ photovoltaic cells between about 500 nm and about 1100 nm. Outside of this range, the CSP system may have higher conversion efficiency than this particular SHJ cell. The hybrid system efficiency was simulated under AM1.5G illumination as a function of both the bandwidth and cut-off wavelength of a band-pass optical filter with 90% transmittance in the pass-band and 90% reflectance in the reject-band, as shown in FIG. 16.

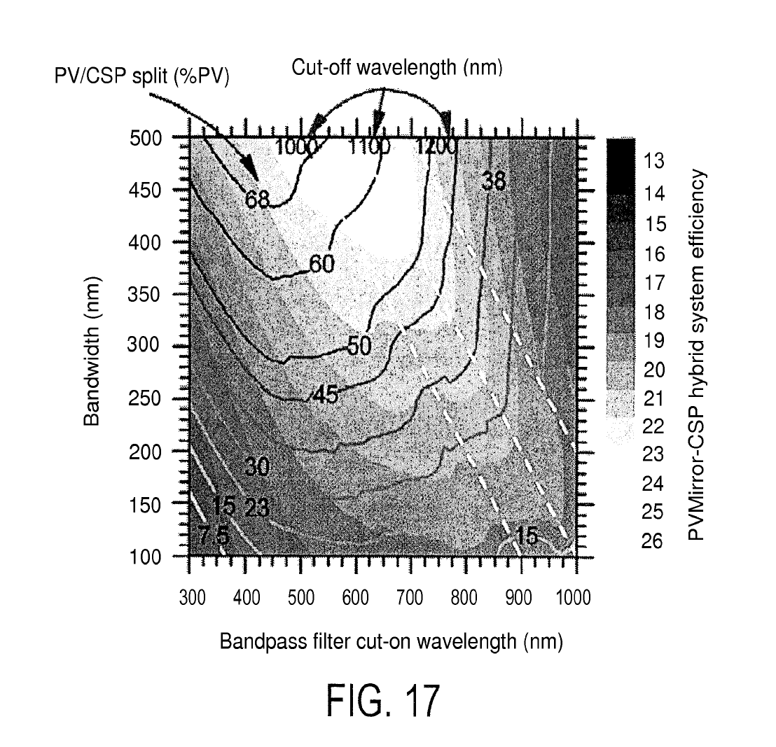

Turning to FIG. 17, it was determined that 25% electrical energy conversion efficiency may be achieved by sending most of the sunlight to the SHJ photovoltaic cells, as the cells are more efficient than CSP at most of their responding wavelengths. However, this provides only a small portion of light to the CSP system, which may be insufficient for operation of a turbine. Further, for a given photovoltaic/CSP split, the highest efficiency was achieved for a band-pass-filter that cuts off at about 1100 nm with a bandwidth associated with the intercept of the corresponding dashed line and the chosen photovoltaic/CSP-split contour line in FIG. 17. Providing a cut-off at longer wavelengths degraded the efficiency as the SHJ photovoltaic cells receive IR light that may not be absorbed. However, providing a cut-off at shorter wavelengths was also identified to be less efficient as the SHJ photovoltaic cells may be more efficient at longer wavelengths close to their band gap, and may be less efficient than a CSP at shorter wavelengths.

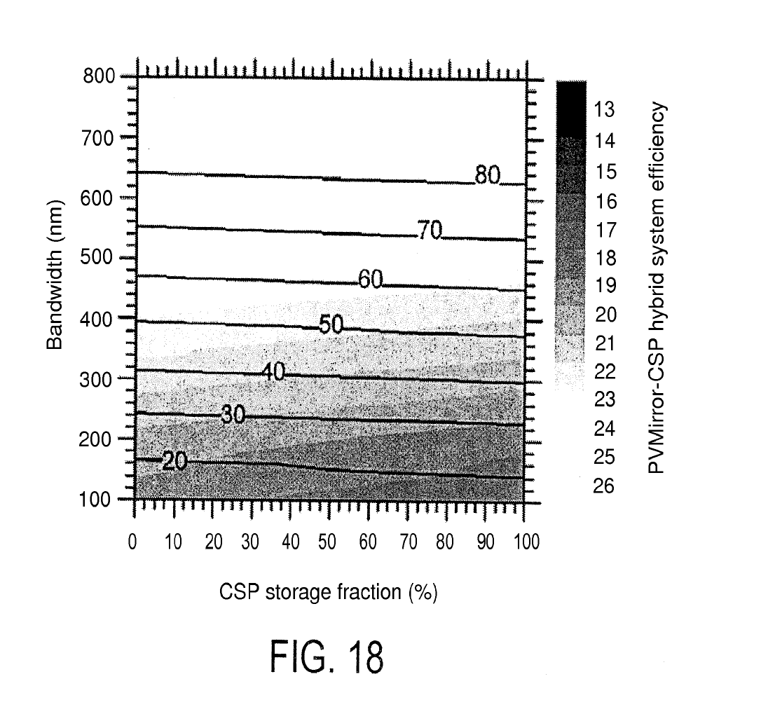

Turning to FIG. 18, the system efficiency was analyzed as a function of bandwidth and thermal storage ratio with a fixed cut-off at 1100 nm wavelength. The hybrid system was found to maintain efficiency over a wider range of storage fractions when sending more light to the SHJ photovoltaic cells, and with a 50/50 power output split of photovoltaic/CSP, 22% electrical energy conversion efficiency was calculated.

1. An apparatus for converting energy from solar radiation having a solar spectrum, the apparatus comprising:
a photovoltaic mirror comprising a plurality of photovoltaic cells, the photovoltaic mirror configured to separate the solar spectrum, absorb a first portion of the solar spectrum, and concentrate a second portion of the solar spectrum at a focus; and
an energy collector spaced from the photovoltaic mirror and positioned at the focus, the energy collector configured for capturing the second portion of the solar spectrum.

2. The apparatus of claim 1 wherein:
the photovoltaic mirror includes at least one filter for diverting the second portion of the solar spectrum to the focus.

3. The apparatus of claim 2 wherein:
the at least one filter comprises an optical coating structured to reflect a range of wavelengths of the solar radiation.

4. The apparatus of claim 3, wherein
the at least one filter comprises at least a first layer and a second layer, the first layer having a refractive index different from the second layer.

5. The apparatus of claim 3 wherein:
the wavelengths are shorter than 700 nanometers.

6. The apparatus of claim 3 wherein:
the wavelengths are larger than 1000 nanometers.

7. The apparatus of claim 3 wherein:
the plurality of photovoltaic cells has a band gap, and
the range of wavelengths is a sub-band gap range.

8. The apparatus of claim 1 wherein:
the plurality of photovoltaic cells generates electricity from a range of absorbed wavelengths representative of a super-band gap range.

9. The apparatus of claim 2 wherein:
the filter comprises an optical coating on at least one of the plurality of photovoltaic cells, each optical coating structured to reflect a range of wavelengths.

10. The apparatus of claim 9 wherein
the filter comprises at least a first layer and a second layer, the first layer having a refractive index different from the second layer.

11. The apparatus of claim 9 wherein:
the wavelengths are shorter than 700 nanometers.

12. The apparatus of claim 9 wherein:
the plurality of photovoltaic cells has a band gap, and
the range of wavelengths is a sub-band gap range.

13. The apparatus of claim 9 wherein:
the plurality of photovoltaic cells generates electricity from a range of absorbed wavelengths representative of a super-band gap range.

14. The apparatus of claim 1 wherein:
the photovoltaic mirror comprises at least one of a transparent parabolic trough, a dish, and a heliostat.

15. The apparatus of claim 1 wherein:
the transparent parabolic trough comprises glass.

16. The apparatus of claim 1 wherein:
the photovoltaic cells are affixed to a support.

17. The apparatus of claim 1 wherein:
the photovoltaic cells face the sun and are attached to a non-sunward side of the photovoltaic mirror.

18. The apparatus of claim 1 wherein:
the photovoltaic cells cover 10% to 100% of a surface of a support.

19. The apparatus of claim 1 wherein:
the photovoltaic cells are affixed to a support via an encapsulation or lamination process.

20. The apparatus of claim 1 wherein:
the photovoltaic cells comprise at least one of crystalline silicon, cadmium telluride, and copper indium gallium selenide.

21. The apparatus of claim 1 wherein:
the photovoltaic cells comprise monocrystalline silicon.

22. The apparatus of claim 1 wherein:
the photovoltaic cells comprise polycrystalline silicon.

23. The apparatus of claim 1 wherein:
the photovoltaic cells are sufficiently flexible so as to conform to a curvature of a support.

24. The apparatus of claim 1 wherein:
at least some of the plurality of photovoltaic cells include a rear reflector.

25. The apparatus of claim 24 wherein:
the rear reflecting coating comprises a metal layer.

26. The apparatus of claim 1 wherein:
the photovoltaic cells are substantially planar.

27. The apparatus of claim 1 wherein:
the photovoltaic cells comprise amorphous silicon/crystalline silicon heterojunction photovoltaic cells.

28. The apparatus of claim 1 wherein:
the energy collector comprises a heat engine.

29. The apparatus of claim 1 wherein:
the energy collector comprises a chemical reaction vessel.

30. The apparatus of claim 1 wherein:
the energy collector comprises at least one of a second plurality of photovoltaic cells.

31. The apparatus of claim 30 wherein:
the second plurality of photovoltaic cells is positioned at the focus for capturing at least some of the second portion of the solar spectrum.

32. The apparatus of claim 1 wherein:
solar radiation absorbed in the photovoltaic cells generates electricity, and solar radiation not absorbed in the photovoltaic cells is reflected and focused on the energy collector.

33. The apparatus of claim 16 wherein:
the support comprises an optical coating structured to reflect a range of wavelengths.

34. The apparatus of claim 1 wherein:
the photovoltaic mirror is segmented.
